(19) United States
(12) Patent Application Publication
(10) Pub. No.: US 2017/0345546 A1
(43) Pub. Date: Nov. 30, 2017

(54) STACKED INDUCTORS

(71) Applicant: QUALCOMM Incorporated, San Diego, CA (US)

(72) Inventor: Miena Armanious, La Jolla, CA (US)

(21) Appl. No.: 15/192,679

(22) Filed: Jun. 24, 2016

Related U.S. Application Data
(60) Provisional application No. 62/342,709, filed on May 27, 2016.

(51) Int. Cl. H01F 27/28; H03H 7/01; H03F 15/00; H03H 7/38; H03B 15/00

(52) U.S. Cl. CPC H01F 27/2804; H03H 7/38; H03B 15/00; H03F 15/00; H03H 7/0138

(57) ABSTRACT

Exemplary embodiments of the disclosure are related to inductors, e.g., at least a pair of planar inductors, for wireless communication apparatus, for example transceivers used in a wireless device. A device may include a first planar inductor configured on a first area of a substrate. The first planar inductor includes a first loop configured to produce a first magnetic field in a first direction and a second loop configured to produce a second magnetic field in a second direction. The device further includes a second planar inductor configured on a second area of the substrate. The second planar inductor includes a third loop configured to produce a third magnetic field in a third direction and a fourth loop configured to produce a fourth magnetic field in a fourth direction. The second area may at least partially overlap the first area.

### CROSS REFERENCE TO RELATED APPLICATIONS

This application claims priority to U.S. Provisional Pat. App. Ser. No. 62/342,709, entitled “STACKED INDUCTORS,” filed May 27, 2016, assigned to the assignee of the present disclosure, the contents of which are hereby incorporated by reference herein in their entirety.

### FIELD

The disclosure relates generally to electronic devices. More specifically, the disclosure includes embodiments related to inductors.

### BACKGROUND

Planar inductors are commonly used in integrated circuit design. Inductors have varying purposes in circuit design. Specifically, inductors may be used in transmitters and receivers for filters and other matching and tuning circuits. Planar inductors may be formed on substrates that include one or more conductive layers separated by one or more dielectric layers on the substrate. The conductive layers can be used to form circuit components that may be separated by the dielectric layers. As circuits become increasingly more complex, the area that is required to build circuits also increases. As more circuit components are placed closer together, some components may cause interfering fields resulting in undesirable interference. Furthermore, additional circuit components may require additional circuit area on the substrate.

Inductors are commonly used in communication circuits for filtering desired and undesired signals. Implementation of a communication transceiver on a substrate may require many inductors for filtering and matching. Inductors may require a significant portion of the substrate when forming integrated circuits. This reduces the area available to other circuit elements. Furthermore, during operation, current passing through an inductor creates a magnetic field which can couple onto nearby circuit components. In some applications it is desirable to minimize coupling between inductors. Such minimization between inductors may require substantial spacing between the inductors in some implementations.

### SUMMARY

Certain embodiments described herein include a device comprising a first inductor and a second inductor. The first inductor may be a planar inductor formed on a substrate and configured with first and second loops arranged in an anti-symmetric shape. The second inductor may be a planar inductor formed on the substrate and configured with third and fourth loops arranged in a symmetric shape. The first and second planar inductors may at least partially overlap on the substrate.

Certain embodiments described herein include a method comprising producing first, second, third, and fourth magnetic fields in respective conducting loops. The first magnetic field may be produced in a first conducting loop in a first direction, The second magnetic field may be produced in a second conducting loop in a second direction. The third magnetic field may be produced in a third conducting loop substantially in the first direction. The fourth magnetic field may be produced in a fourth conducting loop in substantially in the first direction. The first and second conducting loops may at least partially overlap the third and fourth conducting loops.

Certain embodiments described herein include an apparatus comprising first means for inducting and second means for inducting. The first means for inducting may comprise means for producing a first magnetic field in a first direction and means for producing a second magnetic field in a second direction. The second means for inducting may comprise means for producing a third magnetic field substantially in the first direction and means for producing a fourth magnetic field substantially in the first direction. The first means for inducting may at least partially overlap the second means for inducting.

### BRIEF DESCRIPTION OF THE DRAWINGS

FIG. 1 shows a block diagram of a wireless device that may include several inductors, in accordance with an embodiment.

FIG. 2 shows a functional diagram of a pair of inductors, in accordance with an embodiment.

FIG. 3 shows an equivalent circuit for an overlapping pair of planar inductors formed on a substrate, in accordance with an embodiment.

FIG. 4A shows a cross-sectional view of an exemplary layout of a pair of planar inductors, in accordance with an embodiment.

FIG. 4B shows a top view of an exemplary layout of a pair of planar inductors, in accordance with an embodiment.

FIG. 5 shows a perspective view of an exemplary layout of a pair of planar inductors, in accordance with an embodiment.

FIG. 6 shows a top view of an exemplary layout of planar inductors, in accordance with another embodiment.

FIG. 7 shows a perspective view of an exemplary layout of a pair of planar inductors, in accordance with another embodiment.

FIG. 8 is a flowchart illustrating a method, in accordance with one or more exemplary embodiments.

FIG. 9 shows a functional diagram of a pair of inductors for a device, in accordance with an embodiment.

FIG. 10 is a flowchart illustrating a method, in accordance with one or more exemplary embodiments.

FIG. 11 shows a functional diagram of an apparatus including a pair of inductors for a device, in accordance with an embodiment.

### DETAILED DESCRIPTION

The detailed description set forth below in connection with the appended drawings is intended as a description of exemplary embodiments and is not intended to represent the only embodiments in which the present disclosure can be practiced. The term “exemplary” used throughout this description means “serving as an example, instance, or illustration,” and not necessarily as preferred or advantageous over other exemplary embodiments. The detailed description includes specific details for the purpose of providing a thorough understanding of the exemplary embodiments. The exemplary embodiments may be practiced without these specific details. In some instances, well-known structures and devices are shown in block diagram form in order to avoid obscuring the novelty of the exemplary embodiments presented herein.

Inductors are used in a myriad of electronic circuits. Specifically, inductors may be used in filters and matching circuits in transmitters and receivers. An inductor creates a magnetic field in the near and far fields of the inductor. A magnetic field can induce currents in an adjacent second inductor affecting the desired performance of a circuit that incorporates the second inductor. Accordingly, adjacent inductors may be spatially arranged to mitigate interfering induced currents. A device or inductor pair with strong isolation enables closer fabrication and placement of adjacent inductors in more complex circuits.

Certain embodiments described herein allow vertical stacking of multiple inductors, e.g., plan inductors, that exhibit strong isolation. As defined herein, “planar” may include loops that are formed on multiple layers where portions of the loops may be formed on multiple layers connected by an interconnection such as one or more vias. This may reduce the area required to implement two or more inductors by nearly half. Applications for stacked inductors may include two-stage matching circuits, a circuit including a matching inductor and a choke inductor, a circuit including two choke inductors for different bands, and a circuit including two matching circuit inductors for different bands.

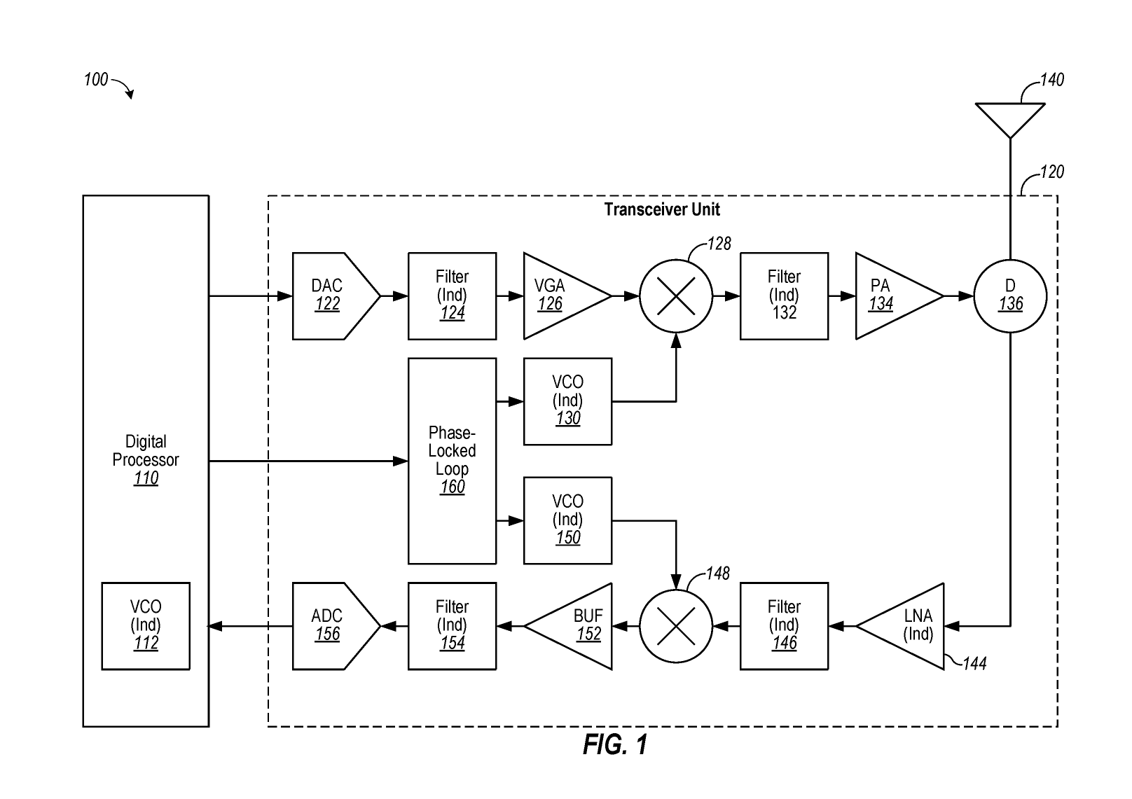

FIG. 1 shows a block diagram of a wireless device 100 that may include several inductors. Certain of these inductors may benefit from strong isolation between adjacent inductors. Specifically, wireless device 100 may be a cellular phone, a personal digital assistant (PDA), a terminal, a handset, a wireless modem, a laptop computer, etc. Wireless device 100 is capable of providing bi-directional communication via a transmit path and a receive path.

On the transmit path, a digital processor 110 may process data to be transmitted and provide a stream of chips to a transceiver unit 120. Within transceiver unit 120, one or more digital-to-analog converters (DACs) 122 may convert the stream of chips to one or more analog signals. The analog signal(s) may be filtered by a filter 124, amplified by a variable gain amplifier (VGA) 126, and frequency upconverted from baseband to RF by a mixer 128 to generate an upconverted signal. The frequency upconversion may be performed based on a transmit local oscillator (LO) signal from a voltage controlled oscillator (VCO) 130. The upconverted signal may be filtered by a filter 132, amplified by a power amplifier (PA) 134, routed through a duplexer (D) 136, and transmitted via an antenna 140.

On the receive path, an RF signal may be received by antenna 140, routed through duplexer 136, amplified by a low noise amplifier (LNA) 144, filtered by a filter 146, and frequency downconverted from RF to baseband by a mixer 148 with a receive LO signal from a VCO 150. The downconverted signal from mixer 148 may be buffered by a buffer (BUF) 152, filtered by a filter 154, and digitized by one or more analog-to-digital converters (ADCs) 156 to obtain one or more streams of samples. The sample stream(s) may be provided to digital processor 110 for processing.

FIG. 1 shows a specific transceiver design. In general, the signal conditioning for each path may be performed with one or more stages of amplifier, filter, and mixer. FIG. 1 shows some circuit blocks that may be used for signal conditioning on the transmit and receive paths. Other designs, however, may be implemented in the device 100. Further, elements illustrated in the trasceiver unit 120 may be implemented in separate module, chips, packages, etc. For example, the PA 134 and/or the suplexer 136 may be implemented in a separate chip and/or module from the remaining elements of the transceiver unit 120. Such separate chip and/or module may be coupled to the remaining elements, for example by traces or other means for coupling between modules on a circuit board.

In the design shown in FIG. 1, transceiver unit 120 includes two VCOs 130 and 150 for the transmit and receive paths, respectively. Digital processor 110 includes a high-speed VCO 112 that may generate clocks for various units within digital processor 110. VCOs 112, 130 and 150 may be implemented with various VCO designs. Each VCO may be designed to operate at a specific frequency or a range of frequencies. For example, VCOs 130 and 150 may be designed to operate at an integer multiple of (e.g., 1, 2, or 4 times) one or more of the following frequency bands—a Personal Communication System (PCS) band from 1850 to 1990 MHz, a cellular band from 824 to 894 MHz, a Digital Cellular System (DCS) band from 1710 to 1880 MHz, a GSM900 band from 890 to 960 MHz, an International Mobile Telecommunications-2000 (IMT-2000) band from 1920 to 2170 MHz, a Global Positioning System (GPS) band from 1574.4 to 1576.4 MHz, Long Term Evolution (LTE) bands, and WiFi bands, or other bands used for wireless communications. A phase locked loop (PLL) 160 may receive control information from digital processor 110 and provide controls for VCOs 130 and 150 to generate the proper transmit and receive LO signals, respectively. I other embodiments, the receive and transmit paths may share a VCO and/or may implement separate PLLs.

A planar inductor (which is denoted as “Ind” in FIG. 1) may be used for various circuit blocks within wireless device 100. For example, the planar inductor may be used in a resonator tank circuit for VCO 112, 130 and/or 150. The inductor may also be used as a load inductor and/or a degeneration inductor for LNA 144. The inductor may also be used for any of the filters in transceiver unit 120. The inductor may also be used before and/or after mixer 128 or 148, after a driver amplifier (not shown in FIG. 1) prior to PA 134, before and/or after duplexer to matching from/to PA 134 and antenna 140 etc. The inductor used in any of these elements may have strong isolation.

The inductor described herein may be implemented on an IC, an analog IC, an RFIC, a mixed-signal IC, an application specific integrated circuit (ASIC), a printed circuit board (PCB), an electronic device, etc. The inductor may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), system-in-package (SIP), etc. As indicated above, the inductor may have strong isolation.

An apparatus implementing the inductor described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

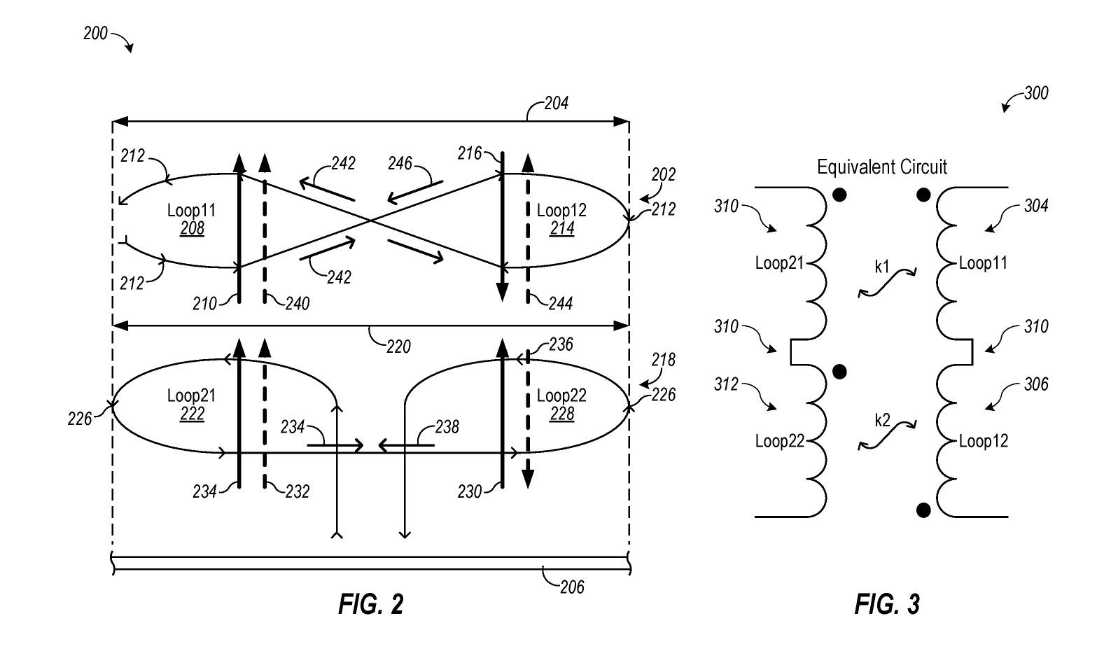

FIG. 2 shows a functional diagram of a pair of inductors 200 for a device. The device may exhibit strong isolation between the inductors.

A device 100 (FIG. 1) may include a pair of inductors 200 having strong near and far field isolation. The pair of inductors 200 includes a first planar inductor 202 arranged on a first area 204 of a substrate 206. The first planar inductor 202 includes a first loop 208 arranged to produce a first magnetic field 210 in a first direction when a conductive current 212 flows in the directions as illustrated. The first planar inductor 202 further includes a second loop 214 configured to produce a second magnetic field 216 in a second direction when the conductive current 212 flows in the directions as illustrated.

In first planar inductor 202, the direction of the first magnetic field 210 and the direction of the second magnetic field 216 may be in substantially opposite directions. Furthermore, first loop 208 and the second loop 214 of the first planar inductor 202 may be configured as a ‘figure-8’ shaped planar inductor or antisymmetric inductor where the current direction is antisymmetric with respect to the vertical plane that divides the first and the second loops. As used herein, “antisymmetric” is defined to include an arrangement of a coil having a first portion of the coil rotated to create a first loop with respect to the other unrotated portion resulting in a second loop, wherein in the presence of a current through the coil, results in a first magnetic field in a first direction in the first loop and a second magnetic field in a second, substantially opposite, direction in the second loop. FIG. 2 illustrates the first planar inductor being tapped on the left side of the figure, but other tap locations may be implemented.

The pair of inductors 200 further includes a second planar inductor 218 arranged on a second area 220 of the substrate 206. The second planar inductor 218 includes a third loop 222 arranged to produce a third magnetic field 224 in a third direction when a conductive current 226 flows in the directions as illustrated. The second planar inductor 218 further includes a fourth loop 228 arranged to produce a fourth magnetic field 230 in a fourth direction when the conductive current 226 flows in the directions as illustrated. The first planar inductor 202 and the second planar inductor 218 are arranged on substrate 206 so area 204 and area 220 at least partially overlap on substrate 206.

In second planar inductor 218, the direction of the third magnetic field 224 and the direction of the fourth magnetic field 230 may be in substantially the same or parallel directions. Furthermore, third loop 222 and the fourth loop 228 of the second planar inductor 218 may be configured as an ‘anti-figure-8’ shaped or symmetric shaped planar inductor where the current direction is symmetric with respect to the vertical plane that divides the third and the fourth loops.

The pair of inductors 200 further project magnetic fields on each other which further induces currents on each other. Specifically, the first magnetic field 210 generated in the first loop 208 projects a magnetic field 232 on the third loop 222. The magnetic field 232 generates an induced current 234 in the second planar inductor 218 in the direction as illustrated. Similarly, the second magnetic field 216 generated in the second loop 214 projects a magnetic field 236 on the fourth loop 228.

The magnetic field 236 generates an induced current 238 in the second planar inductor 218 in the direction as illustrated. Based upon the relative field strengths of the magnetic field 232 and the magnetic field 236 with respect to each other, the induced current 234 and the induced current 238 may substantially cancel or counteract each other resulting in little near and far field effects generated by the first planar inductor 202 on the second planar inductor 218.

As stated, the pair of inductors 200 further project magnetic fields on each other which further induces currents on each other. Specifically, the third magnetic field 224 generated in the third loop 222 projects a magnetic field 240 on the first loop 208. The magnetic field 240 generates an induced current 242 in the first planar inductor 202 in the direction as illustrated. Similarly, the fourth magnetic field 230 generated in the fourth loop 228 projects a magnetic field 244 on the second loop 214.

The magnetic field 244 generates an induced current 246 in the first planar inductor 202 in the direction as illustrated. Based upon the relative field strengths of the magnetic field 240 and the magnetic field 244 with respect to each other, the induced current 242 and the induced current 246 may substantially cancel or counteract each other resulting in little near and far field effects generated by the second planar inductor 218 on the first planar inductor 202.

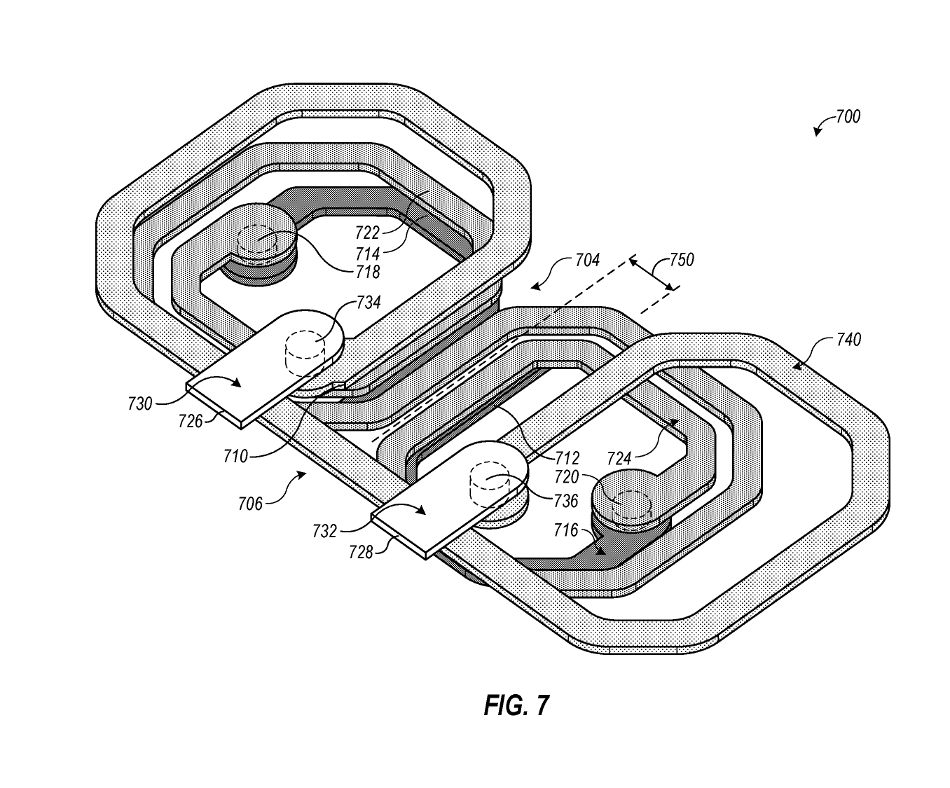

As will be further illustrated below, the first planar inductor 202 and the second planar inductor 218 may symmetrically overlap as illustrated in FIG. 2, or may asymmetrically overlap by an offset as shown below with respect to FIG. 7. Asymmetrical overlapping can create mild coupling which may have advantages for some specific circuit applications.

FIG. 3 shows an equivalent circuit 300 for an overlapping pair of planar inductors 200 (FIG. 2) formed on a substrate, in accordance with an aspect. The equivalent circuit 300 of the pair of planar inductors 200 includes a first winding 302 comprised of an inductance₁₁ 304 resulting from the first loop 208 (FIG. 2) and an inductance₁₂ 306 resulting from the second loop 214. The equivalent circuit 300 of the pair of planar inductors 200 further includes a second winding 308 comprised of an inductance₁₁ 310 resulting from the third loop 222 (FIG. 2) and an inductance₂₂ 312 resulting from the fourth loop 228.

The inductance₁₁ 304 and the inductance₂₁ 310 are related by a coupling coefficient k1 resulting from mutual magnetic flux between the first loop 208 of the first planar inductor 202 and the third loop 222 of the second planar inductor 218. Further, the inductance₁₂ 306 and the inductance₂₂ 312 are related by a coupling coefficient k2 resulting from mutual magnetic flux between the second loop 214 of the first planar inductor 202 and the fourth loop 228 of the second planar inductor 218.

The magnitudes of coupling coefficients k1 and k2 may be adjusted by altering the overlapping portion of the first planar inductor 202 with the second planar inductor 218 on the substrate 206. An overall magnetic coupling coefficient k could be minimal (even zero) to a desired coupling coefficient for circuits that may advantageously operate with magnetic coupling. Further, the polarity of the respective inductances of the windings are also illustrated in FIG. 3.

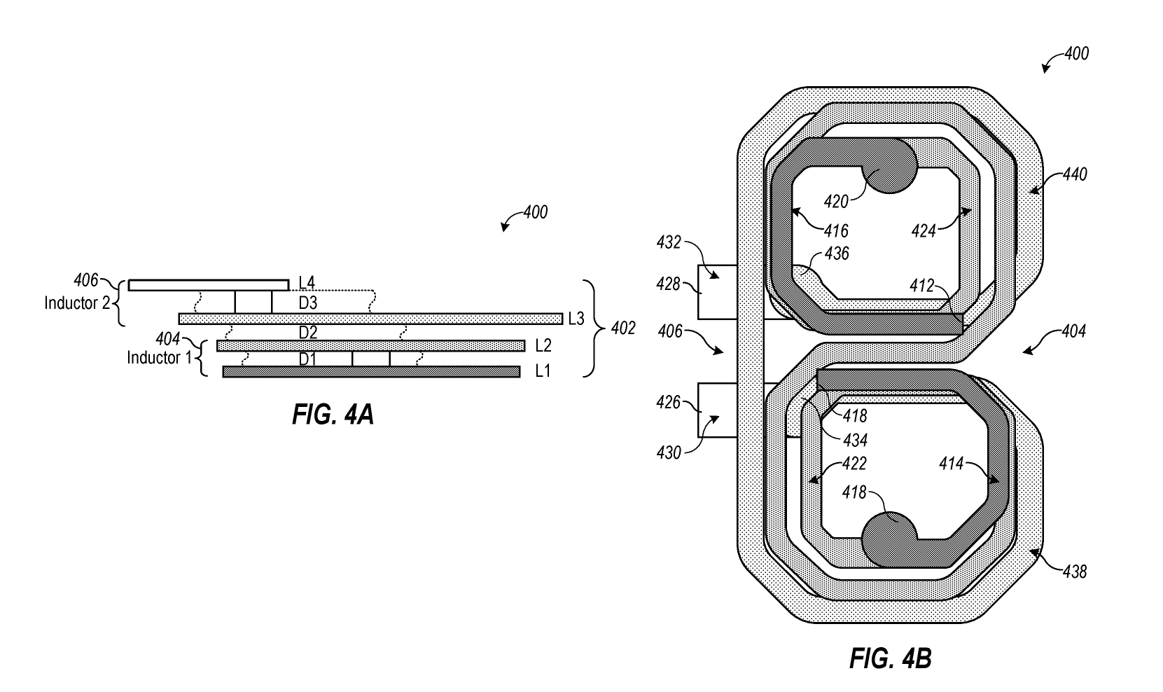

FIG. 4A shows a cross-sectional view of an exemplary layout of a pair of planar inductors 400, in accordance with an aspect. The pair of planar inductors 400 may exhibit reduced coupling as compared to known inductors. The pair of planar inductors 400 is formed on a substrate 402. The substrate 402 may include conductive layers L1-L4 with dielectric layers D1-D3 providing isolation to the conductive layers. Two or more conductive layers may be used for each planar inductor with vias electrically connecting the layers together. A first planar inductor 404 including first loop 407 and second loop 409 may be formed from conductive layer L1 coupling to conductive layer L2 through vias passing through dielectric layer D1. A second planar inductor 406 including third loop 411 and fourth loop 413 may be formed from conductive layer L3 coupling to conductive layer L4 through vias passing through dielectric layer D3. The dielectric layer D2 provides electrical isolation between the first planar inductor 404 and the second planar inductor 406.

FIG. 4B shows a top view of an exemplary layout of a pair of planar inductors 400, in accordance with an aspect. The pair of planar inductors 400 may exhibit reduced coupling as compared to known inductors. The top view is illustrated for clarity with conductive layer L1 being illustrated on top with conductive layer L4 being illustrated furthest to the back. The pair of planar inductors 400 may include the first planar inductor 404 and the second planar inductor 406.

The first planar inductor 404 may include terminals 410 and 412 located on an outer layer such as the conductive layer L1. A first portion 414 and a second portion 416 of the first planar inductor 404 also may be formed on the conductive layer L1. A via 418 and via 420 may respectively couple the first portion 414 and the second portion 416 to a third portion 422 and a fourth portion 424 of the first planar inductor 404. The third portion 422 and the fourth portion 424 may be formed on the conductive layer L2. The first portion 414, the second portion 416, the third portion 422 and the fourth portion 424 collectively form the first planar inductor 404 in a ‘figure-8’ shape or an anti-symmetric shape.

The second planar inductor 406 may include terminals 426 and 428 located on an outer layer such as the conductive layer L4. A first portion 430 and a second portion 432 of the second planar inductor 406 also may be formed on the conductive layer L4. A via 434 and via 436 may respectively couple the first portion 430 and the second portion 432 to a third portion 438 and a fourth portion 440 of the second planar inductor 406. The third portion 438 and the fourth portion 440 may be formed on the conductive layer L3. The first portion 430, the second portion 432, the third portion 438 and the fourth portion 440 collectively form the second planar inductor 406 in an ‘anti-figure-8’ shape or symmetric shape.

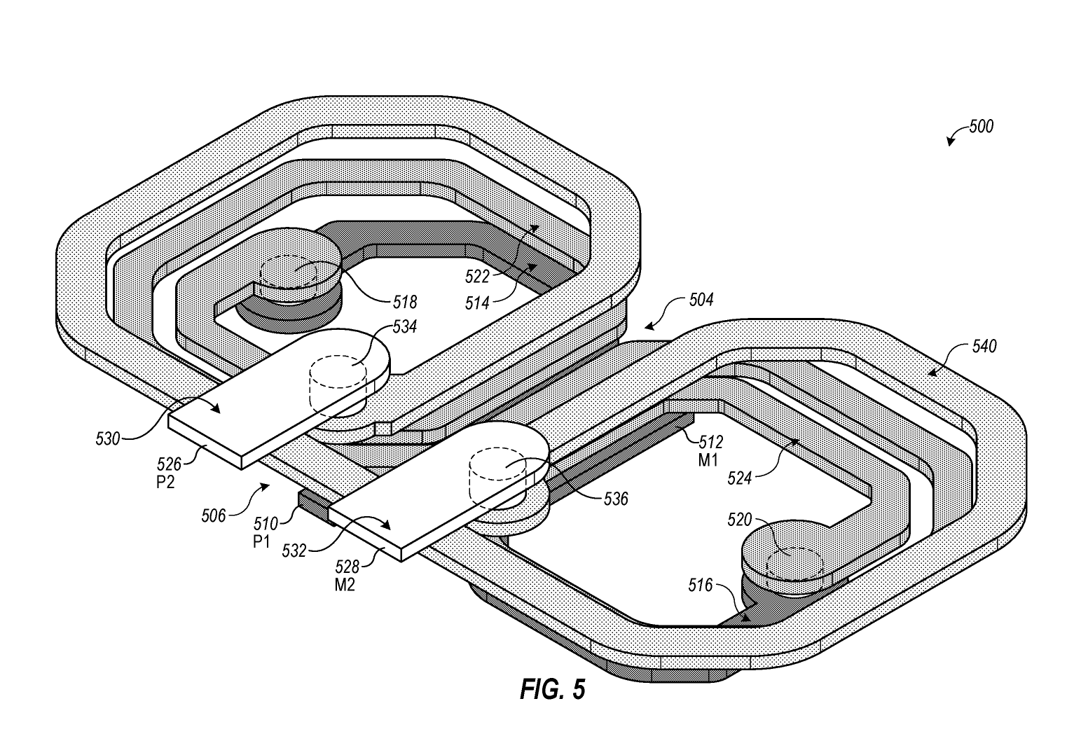

FIG. 5 shows a perspective view of an exemplary layout of a pair of planar inductors 500, in accordance with an aspect. In FIG. 5, the pair of planar inductors 500 provides an inverted view from FIG. 4B. Specifically, the conductive layer L4 is illustrated on top with conductive layer L1 being illustrated furthest to the back. The pair of planar inductors 500 may include the first planar inductor 504 and the second planar inductor 506.

The first planar inductor 504 including first loop 507 and second loop 509 may include terminals 510 and 512 located on an outer layer such as the conductive layer L1. A first portion 514 and a second portion 516 of the first planar inductor 504 also may be formed on the conductive layer L1. A via 518 and via 520 may respectively couple the first portion 514 and the second portion 516 to a third portion 522 and a fourth portion 524 of the first planar inductor 504. The third portion 522 and the fourth portion 524 may be formed on the conductive layer L2. The first portion 514, the second portion 516, the third portion 522 and the fourth portion 524 collectively form the first planar inductor 504 in a ‘figure-8’ shape or an anti-symmetric shape.

The second planar inductor 506 including third loop 511 and fourth loop 513 may include terminals 526 and 528 located on an outer layer such as the conductive layer L4. A first portion 530 and a second portion 532 of the second planar inductor 506 also may be formed on the conductive layer L4. A via 534 and via 536 may respectively couple the first portion 530 and the second portion 532 to a third portion 538 and a fourth portion 540 of the second planar inductor 506. The third portion 538 and the fourth portion 540 may be formed on the conductive layer L3. The first portion 530, the second portion 532, the third portion 538 and the fourth portion 540 collectively form the second planar inductor 506 in an ‘anti-figure-8’ shape or symmetric shape.

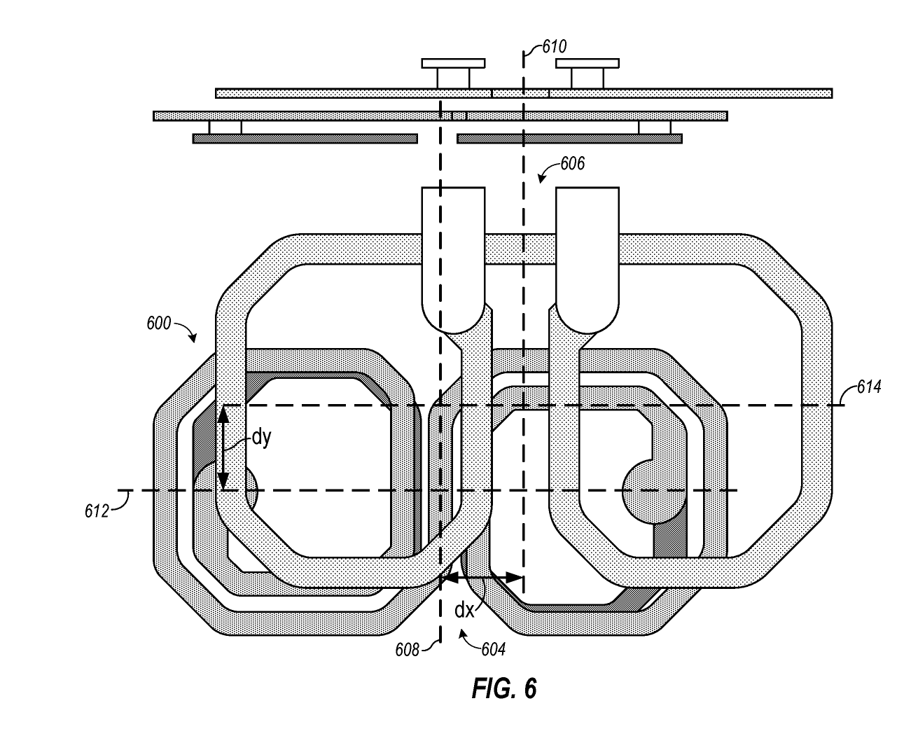

FIG. 6 shows a top view of an exemplary layout of planar inductors 600, in accordance with another aspect. The inductors 600 may exhibit reduced coupling as compared to known inductors. In FIG. 6, the first planar inductor 604 and the second planar inductor 606 may be arranged with an x-direction offset to their axes of symmetry 608, 610. The axes of symmetry may be defined substantially from the centerpoints of the loops formed from the inductors. Furthermore, the first planar inductor 604 including first loop 607 and second loop 609 and the second planar inductor 606 including third loop 611 and fourth loop 613 may be arranged with a y-direction offset to their axes 612, 614.

Magnetic coupling may be less sensitive to offset or misalignment in an x-direction because the mutual flux symmetry may not be broken. Further, y-direction offset or misalignment may have a subtle effect on magnetic coupling since the mutual flux symmetry is broken. While not illustrated in FIG. 6, isolation from misalignment may be further improved by forming the loops of the second planar inductor on the outside layer, namely layer L4. Table 1 provides example values for a simulation of two inductors with metal trace thickness and width of 18 um and 60 um on a laminate module with layer-to-layer spacing of 25 um. The overall inductor area is approximately 1150 um×660 um.

TABLE 1
Simulation Results for Offset of Planar Inductors

| dx | dy | k@800 MHz | k@1.8 GHz | k@2.6 GHz |
|---|---|---|---|---|
| 20 um | 0 | 0.04 | 0.045 | 0.053 |
| 40 um | 0 | 0.067 | 0.073 | 0.082 |
| 0 | 20 um | 0.008 | 0.013 | 0.022 |
| 0 | 40 um | 0.01 | 0.016 | 0.024 |
| 50 um | 50 um | 0.065 | 0.062 | 0.056 |

As noted in Table 1, offsets or misalignments in the x-direction (dx) result in very low magnetic coupling. Further, offsets or misalignments in the y-direction (dy) result in slight magnetic coupling but still provide acceptable coupling levels (e.g., |k|<0.1) in the near and far fields.

FIG. 7 shows a perspective view of an exemplary layout of a pair of planar inductors 700, in accordance with another aspect. The pair of planar inductors 700 may exhibit imbalance. Specifically, a loop 713 of one of the first or second planar inductors is offset from symmetry with a corresponding loop in the other one of the first and second planar loops by an offset 750. The pair of planar inductors 700 may include the first planar inductor 704 and the second planar inductor 706.

The first planar inductor 704 including first loop 707 and second loop 709 may include terminals 710 and 712 located on an outer layer such as the conductive layer L1. A first portion 714 and a second portion 716 of the first planar inductor 704 also may be formed on the conductive layer L1. A via 718 and via 720 may respectively couple the first portion 714 and the second portion 716 to a third portion 722 and a fourth portion 724 of the first planar inductor 704. The third portion 722 and the fourth portion 724 may be formed on the conductive layer L2. The first portion 714, the second portion 716, the third portion 722 and the fourth portion 724 collectively form the first planar inductor 704 in a ‘figure-8’ shape or anti-symmetric shape.

The second planar inductor 706 including third loop 711 and fourth loop 713 may include terminals 726 and 728 located on an outer layer such as the conductive layer L4. A first portion 730 and a second portion 732 of the second planar inductor 706 also may be formed on the conductive layer L4. A via 734 and via 736 may respectively couple the first portion 730 and the second portion 732 to a third portion 738 and a fourth portion 740 of the second planar inductor 706. The third portion 738 and the fourth portion 740 may be formed on the conductive layer L3. The first portion 730, the second portion 732, the third portion 738 and the fourth portion 740 collectively form the second planar inductor 706 in an ‘anti-figure-8’ shape or symmetric shape.

As stated, shifting of one of the loops of one planar inductor to be offset from a loop from another planar inductor may introduce an unbalance in the total magnetic flux of the pair of planar inductors. For example, an offset of as little as 100 um may lead to the introduction of a coupling coefficient k of 0.09. FIG. 7 illustrates a single loop being offset from symmetrically overlapping with an opposing respective planar inductor, however, the entire planar inductor may be asymmetrically offset as shown in FIG. 7. It is further contemplated that a loop from each planar inductor could have differing offsets to generate desirable magnetic flux coupling coefficients.

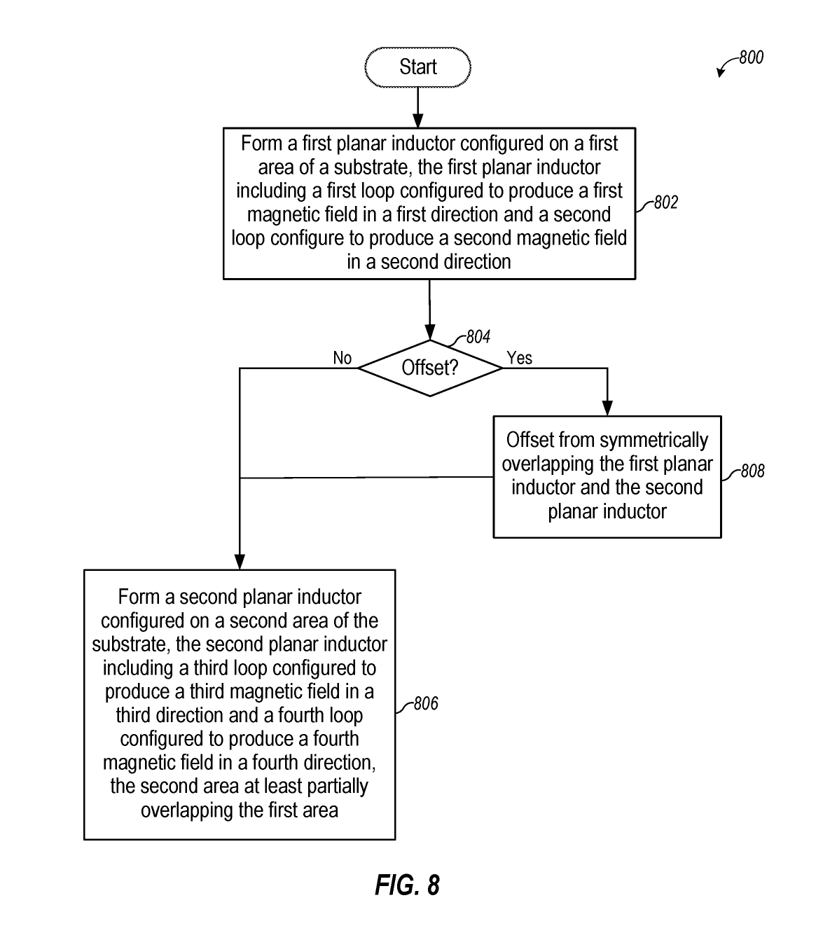

FIG. 8 is a flowchart illustrating a method 800, in accordance with one or more exemplary embodiments. Method 800 may include forming, in a step 802, a first planar inductor configured on a first area of a substrate. The first planar inductor including a first loop configured to produce a first magnetic field in a first direction and a second loop configured to produce a second magnetic field in a second direction. Method 800 may further include determining, in a query step 804, if an offset between planar inductors is to be formed. When an offset is not determined, method 800 further includes forming, in a step 806, a second planar inductor configured on a second area of the substrate, the second planar inductor including a third loop configured to produce a third magnetic field in a third direction and a fourth loop configured to produce a fourth magnetic field in a fourth direction. The second area at least partially overlapping the first area. When an offset is determined in step 804, offsetting, in a step 808, from symmetrically overlapping the first planar inductor and the second planar inductor.

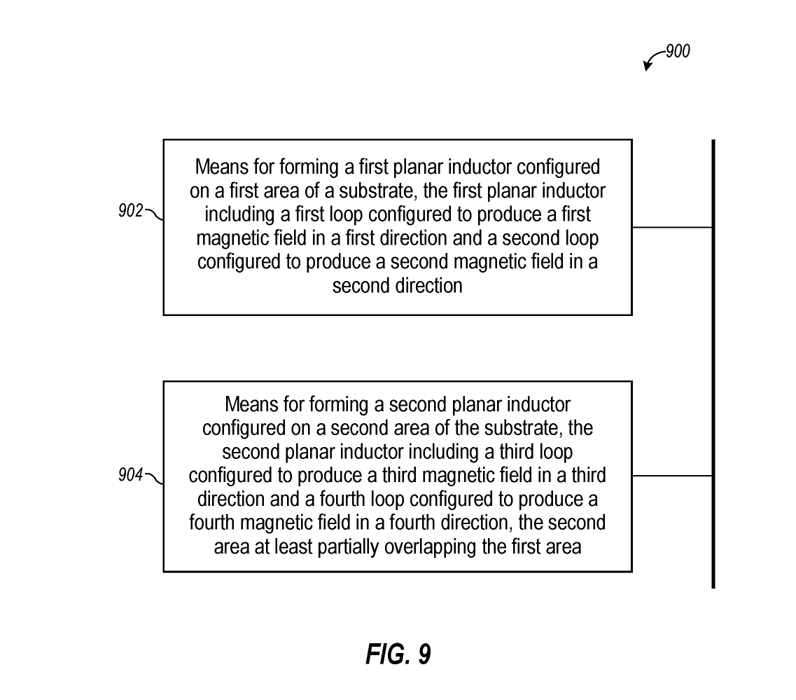

FIG. 9 shows an exemplary embodiment of receiver device 900. In one exemplary embodiment, device 900 is implemented by one or more modules configured to provide the functions as described herein. For example, in an aspect, each module comprises hardware and/or hardware executing software.

Device 900 comprises means 902 for forming a first planar inductor configured on a first area of a substrate, the first planar inductor including a first loop configured to produce a first magnetic field in a first direction and a second loop configured to produce a second magnetic field in a second direction.

Device 900 also comprises a means 904 for forming a second planar inductor configured on a second area of the substrate, the second planar inductor including a third loop configured to produce a third magnetic field in a third direction and a fourth loop configured to produce a fourth magnetic field in a fourth direction, the second area at least partially overlapping the first area.

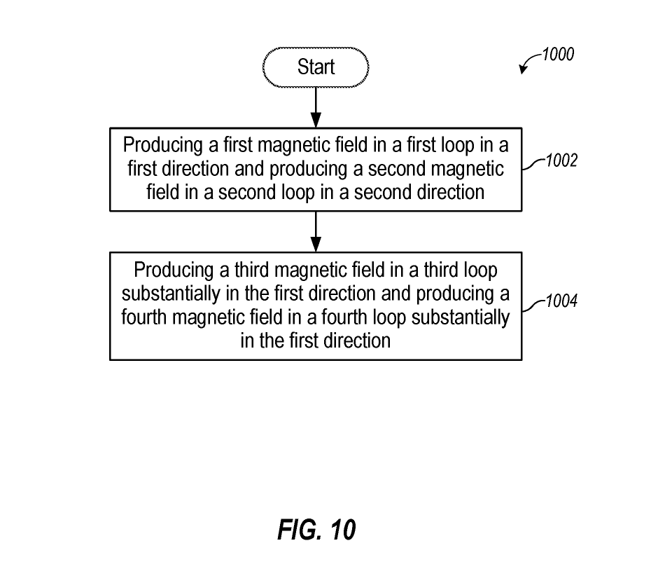

FIG. 10 is a flowchart illustrating a method, in accordance with one or more exemplary embodiments. In one exemplary embodiment, a method 1000 may include producing, in a step 902, a first magnetic field in a first loop in a first direction and producing a second magnetic field in a second loop in a second direction. Method 1000 may further include producing, in step 1004, a third magnetic field in a third loop substantially in the first direction and producing a fourth magnetic field in a fourth loop substantially in the first direction. The first and second loops may at leas partially overlap with the third and fourth loops.

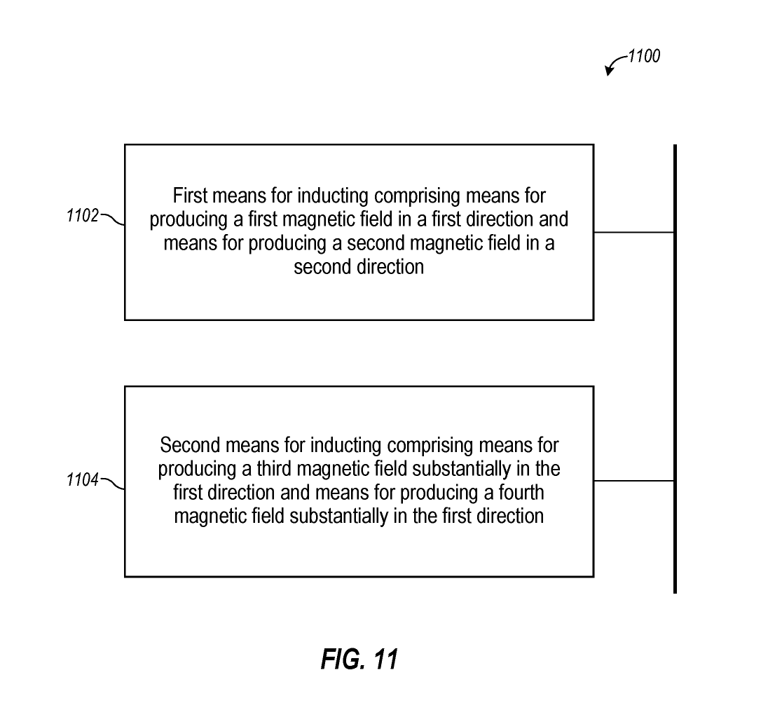

FIG. 11 shows a functional diagram of an apparatus 1100 including a pair of inductors for a device, in accordance with an embodiment. In one exemplary embodiment, an apparatus 1100 is implemented by one or more modules configured to provide the functions as described herein. For example, in an aspect, each module comprises hardware and/or hardware executing software.

The apparatus 1100 comprises a means 1102 for inducting comprising means for producing a first magnetic field in a first direction and means for producing a second magnetic field in a second direction. The apparatus 1100 further comprises a means 1104 for inducting comprising means for producing a third magnetic field substantially in the first direction and means for producing a fourth magnetic field substantially in the first direction. The apparatus 1100 may further be configured such that the first means for inducting at least partially overlaps the second means for inducting.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. The described functionality may be implemented in varying ways for each particular application, but such implementation decisions are not departures from the scope of the exemplary embodiments of the disclosure.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise non-transitory media such as RAM, ROM, EEPROM, CD-ROM or other optical disk storage, magnetic disk storage or other magnetic storage devices, or can comprise any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above are also be included within the scope of computer-readable media.

The previous description of the disclosed exemplary embodiments is provided to enable any person skilled in the art to make or use the present disclosure. Various modifications to these exemplary embodiments will be readily apparent to those skilled in the art, and the generic principles defined herein may be applied to other embodiments without departing from the spirit or scope of the disclosure. Thus, the present disclosure is not intended to be limited to the exemplary embodiments shown herein but is to be accorded the widest scope consistent with the principles and novel features disclosed herein.

What is claimed is:

1. A device comprising:
a first planar inductor disposed on a substrate and configured with first and second loops arranged in an anti-symmetric shape; and
a second planar inductor disposed on the substrate and configured with third and fourth loops arranged in a symmetric shape, the first and second planar inductors at least partially overlapping on the substrate.

2. The device of claim 1, wherein the first planar inductor and the second planar inductor symmetrically overlap.

3. The device of claim 1, wherein the first planar inductor and the second planar inductor are offset from symmetrically overlapping.

4. The device of claim 1, wherein one of the first and second loops symmetrically overlaps one of the third and fourth loops and the other one of the first and second loops is offset from symmetrically overlapping the other one of the third and fourth loops.

5. The device of claim 1, wherein the first loop is configured to produce a first magnetic field in a first direction and the second loop is configured to produce a second magnetic field in a second direction substantially opposite the first direction.

6. The device of claim 5, wherein the third loop is configured to produce a third magnetic field in a third direction and the fourth loop is configured to produce a fourth magnetic field in a fourth direction substantially the same as the third direction.

7. The device of claim 6, wherein current induced in the first planar inductor by the third and fourth magnetic fields is substantially zero, and wherein current induced in the second planar inductor by the first and second magnetic fields is substantially zero.

8. The device of claim 1, wherein the device comprises a filter, a voltage controlled oscillator, or a low noise amplifier.

9. A method comprising:
producing a first magnetic field in a first conducting loop in a first direction and producing a second magnetic field in a second conducting loop in a second direction;
producing a third magnetic field in a third conducting loop substantially in the first direction and producing a fourth magnetic field in a fourth conducting loop substantially in the first direction, the first and second conducting loops at least partially overlapping the third and fourth conducting loops.

10. The method of claim 9, wherein the first direction and the second direction are substantially opposite.

11. The method of claim 9, wherein the first, second, third, and fourth conducting loops are substantially planar.

12. The method of claim 11, wherein the first and second conducting loops are formed on first and second layers of a substrate and the third and fourth conducting loops are formed on third and fourth layers of the substrate.

13. The method of claim 9, further comprising processing a radio frequency signal based at least in part on the producing the first, second, third, and fourth magnetic fields.

14. The method of claim 13, wherein the processing comprising filtering or amplifying the radio frequency signal.

15. An apparatus comprising:
first means for inducting comprising means for producing a first magnetic field in a first direction and means for producing a second magnetic field in a second direction; and
second means for inducting comprising means for producing a third magnetic field substantially in the first direction and means for producing a fourth magnetic field substantially in the first direction,
wherein the first means for inducting at least partially overlaps the second means for inducting.

16. The apparatus of claim 15, wherein the first direction and the second direction are substantially opposite.

17. The apparatus of claim 15, wherein the means for producing a first magnetic field, means for producing a second magnetic field, means for producing a third magnetic field, and means for producing a fourth magnetic field each comprise a conducting loop.

18. The apparatus of claim 15, wherein the first means for inducting are disposed on first and second layers of a substrate and the second means for inducting are disposed on third and fourth layers of the substrate.

19. The apparatus of claim 15, wherein the apparatus is included in a device at least partially configured to process radio frequency signals.

20. The apparatus of claim 15, wherein the first inductor comprises a first planar inductor and/or the second inductor comprises a second planar inductor.
